(19) United States
(12) Patent Application Publication
(10) Pub. No.: US 2025/0233352 A1
(43) Pub. Date: Jul. 17, 2025

(54) RECONFIGURABLE CARTRIDGE BASED SUBSEA CONNECTOR APPARATUS AND SYSTEM

(71) Applicant: The United States of America as represented by the Secretary of the Navy, San Diego, CA (US)

(72) Inventors: Daniel Sura, San Diego, CA (US); Colin Fera, San Diego, CA (US)

(73) Assignee: The United States of America as represented by the Secretary of the Navy, San Diego, CA (US)

(21) Appl. No.: 18/410,829

(22) Filed: Jan. 11, 2024

(51) Int. Cl. H01R 13/523; H01R 13/52; H01R 13/629

(52) U.S. Cl. CPC H01R 13/523; H01R 13/521; H01R 13/5219; H01R 13/629

(57) ABSTRACT

A reconfigurable cartridge based subsea connector apparatus and system comprising a connector, further comprising a face comprising a plurality of female sockets, at least three connector sealing surfaces, and a female locking sleeve surrounding the outer edge of the face and operable to provide a compressive seal when mated with a male locking sleeve; a symmetrical or asymmetrical connector, electrically connected to a symmetrical cable, configured to selectively couple with the connector; and a dual-sided cartridge configured to selectively intermediate a connection between the connector and symmetrical connector, further comprising a printed circuit board. In some embodiments, the cartridge is interchangeable and reusable.

### STATEMENT REGARDING FEDERALLY-SPONSORED RESEARCH AND DEVELOPMENT

The United States Government has ownership rights in this invention. Licensing inquiries may be directed to Office of Research and Technical Applications Naval Information Warfare Center Pacific, Code 72120, San Diego, CA, 92152; telephone (619) 553-5118; email: niwc_patent.fct@us.navy.mil, referencing Navy Case No. 113,579.

### BACKGROUND

Subsea connector and cable assemblies are commonly used in commercial and government applications, including in submersible underwater vehicles, moored buoys, and sensor based systems that collect data underwater. However, existing subsea connectors and cable assemblies have several problems. One exemplary problem is male and female connectors having disparate geometries. Multiple connector geometries add unnecessary complexity in machine tooling for manufacturing and increases overhead for maintaining dissimilar part designs. A second problem with subsea connector and cable assemblies is their ability to be reconfigured or reused. Cables and connectors assemblies are typically use-case dependent and designed to match requirements of an external system. Therefore, a change of an external system's design will frequently necessitate a change in connector and cable assemblies. These changes impact many of the assembly's core components such as cable pinout, sensor types, or port functionality. A complete reconfiguration is often required in these circumstances, leading to expensive redesign and labor intensive work to implement the new cabling. Accordingly, there is a need for a subsea connector and cable assembly that is readily reusable and reconfigurable.

### SUMMARY

According to illustrative embodiments, a symmetrical subsea connector apparatus, comprising: a connector, further comprising: a face comprising a plurality of female sockets embedded in the face, at least three connector sealing surfaces surrounding the plurality of female sockets, and at least one alignment hole, and a female locking sleeve surrounding the outer edge of the face and operable to provide a compressive seal when mated with a male locking sleeve; a symmetrical connector configured to selectively couple with the connector, further comprising: a symmetrical face comprising a plurality of symmetrical female sockets embedded in the symmetrical face, at least three sealing surfaces surrounding the plurality of symmetrical female sockets, and a plurality of symmetrical alignment holes, and the male locking sleeve surrounding the outer edge of the symmetrical face operable to provide a compressive seal when mated with the female locking sleeve; and a dual-sided cartridge configured to selectively intermediate a connection between the connector and symmetrical connector, further comprising: a printed circuit board (PCB), having a first side, a second side, and a plurality of pass through holes further comprising a plurality of interconnections, a plurality of male contact pins coupled to each of the first side and the second side of the PCB, wherein the configuration of the plurality of male contact pins is aligned to selectively mate with the plurality of female sockets on the first side and the plurality of symmetrical female sockets on the second side, and wherein each male contact pin is interconnected is a pin on the other side, at least three sealing surfaces on each side surrounding the plurality of male contact pins, at least two alignment pins protruding from each of the first side and the second side of the PCB, wherein the configuration of the alignment pins aligned to selectively mate with the alignment holes of each of the face and symmetrical face.

Additionally, a asymmetrical subsea connector apparatus, comprising: a connector, further comprising: a face comprising a plurality of female sockets embedded in the face, at least three connector sealing surfaces surrounding the plurality of female sockets, and at least one alignment hole, and a female locking sleeve surrounding the outer edge of the face and operable to provide a compressive seal when mated with a male locking sleeve; a asymmetrical connector configured to selectively couple with the connector, further comprising: a asymmetrical face comprising a plurality of asymmetrical female sockets embedded in the asymmetrical face, at least two asymmetrical connector sealing surfaces surrounding the plurality of asymmetrical female sockets, and a plurality of alignment holes, and the male locking sleeve surrounding the outer edge of the asymmetrical face operable to provide a compressive seal when mated with the female locking sleeve; and a dual-sided cartridge configured to selectively intermediate a connection between the connector and asymmetrical connector, further comprising: a printed circuit board (PCB), having a first side, a second side, and a plurality of pass through holes further comprising a plurality of interconnections, a plurality of male contact pins coupled to the first side and the second side of the PCB, wherein the configuration of the plurality of male contact pins is aligned to selectively mate with the plurality of female sockets on the first side and the plurality of female sockets on the second side, at least three sealing surfaces on each side surrounding the plurality of male contact pins, at least two alignment pins protruding from each of the first side and the second side of the PCH, wherein the configuration of the alignment pins aligned to selectively mate with the alignment holes of each of the face and asymmetrical face.

Additionally, a subsea connector system, comprising a first connector further comprising: a face comprising a plurality of female sockets embedded in the face, at least three connector sealing surfaces surrounding the plurality of female sockets, and at least one alignment hole, and a female locking sleeve surrounding the outer edge of the face and operable to provide a compressive seal when mated with a male locking sleeve; a second connector configured to selectively couple with the connector, further comprising: a second face comprising a plurality of second female sockets embedded in the second face, at least three connector second sealing surfaces surrounding the plurality of second female sockets, and a plurality of alignment holes, and the male locking sleeve surrounding the outer edge of the second face operable to provide a compressive seal when mated with the female locking sleeve; and a plurality of interchangeable cartridges, each configured to selectively intermediate a connection between the connector and second connector, and wherein each of the plurality of interchangeable cartridges provides a unique connection configuration, further comprising: a printed circuit board (PCB) having a first side and a second side, a plurality of male contact pins coupled to the first side and the second side of the PCB, wherein the configuration of the plurality of male contact pins is aligned to selectively mate with the plurality of female sockets on the first side and the plurality of female sockets on the second side, at least three sealing surfaces on each side surrounding the plurality of male contact pins, at least two alignment pins protruding from each of the first side and the second side of the PCB, wherein the configuration of the alignment pins aligned to selectively mate with the alignment holes of each of the face and second face.

It is an objective to provide a Reconfigurable Cartridge Based Subsea Connector Apparatus and System that offers numerous benefits, including a symmetrical cable design on both sides of the cartridge, which may reduce the overall complexity and would make a cable assembly cheaper to manufacturer and thus cheaper for consumers. Additionally, the symmetrical design greatly simplifies the sparing process and makes the assembly more reusable and easier to fix on the spot.

Furthermore, the printed-circuit-board based (PCB) cartridge provides unique advantages. For an example, an operator may quickly interchange connection configuration without having to: deconstruct each connection and repot a new one, procure new cabling and pot over the new soldered connections, or to break open pressure housings and rewire all internal electronics. The cartridge may be swapped out swiftly, providing significant advantages for the user. In some embodiments, is swapped by disconnecting the cable connectors, removing the PCB cartridge, attaching the new PCB cartridge, and reconnecting the cable connections. The PCB may be customized to the particular use case by making electrical connections (e.g. soldering or adding wire traces) meet the system requirements and then potting in a compound such as urethane to ensure waterproofing. This apparatus and system enable a process much quicker and cheaper than current methods, apparatuses, or systems.

It is an object to overcome the limitations of the prior art.

These, as well as other components, steps, features, objects, benefits, and advantages, will now become clear from a review of the following detailed description of illustrative embodiments, the accompanying drawings, and the claims.

### BRIEF DESCRIPTION OF THE DRAWINGS

The accompanying drawings, which are incorporated in and form a part of the specification, illustrate example embodiments and, together with the description, serve to explain the principles of the invention. Throughout the several views, like elements are referenced using like references. The elements in the figures are not drawn to scale and some dimensions are exaggerated for clarity. In the drawings:

FIG. 1A shows an exemplary isometric illustration of a subsea connector in a connected position.

FIG. 1B shows an exemplary isometric illustration of a subsea connector with a bulkhead connector.

FIG. 2 shows an exemplary isometric illustration of subsea connector in an open position.

FIG. 3 shows an exemplary wireframe illustration of a subsea connector in a connected position.

FIG. 4 shows an exemplary isometric illustration of a potted printed circuit board (PCB) cartridge.

FIG. 5A shows an exemplary front-view illustration of a PCB assembly having PCB traces.

FIG. 5B shows an exemplary front-view illustration of a PCB assembly having soldered connections.

FIG. 5C shows an exemplary side-view illustration of a PCB assembly.

FIG. 6A show exemplary pinout configuration for a side A of a PCB assembly.

FIG. 6B show exemplary pinout configuration for a side B of a PCB assembly.

### DETAILED DESCRIPTION OF EMBODIMENTS

The disclosed apparatus and system below may be described generally, as well as in terms of specific examples and/or specific embodiments. For instances where references are made to detailed examples and/or embodiments, it should be appreciated that any of the underlying principles described are not to be limited to a single embodiment, but may be expanded for use with any of the other apparatus and system described herein as will be understood by one of ordinary skill in the art unless otherwise stated specifically.

References in the present disclosure to “one embodiment,” “an embodiment,” or any variation thereof, means that a particular element, feature, structure, or characteristic described in connection with the embodiments is included in at least one embodiment. The appearances of the phrases “in one embodiment,” “in some embodiments,” and “in other embodiments” in various places in the present disclosure are not necessarily all referring to the same embodiment or the same set of embodiments.

As used herein, the terms “comprises,” “comprising,” “includes,” “including,” “has,” “having,” or any variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or.

Additionally, use of words such as “the,” “a,” or “an” are employed to describe elements and components of the embodiments herein; this is done merely for grammatical reasons and to conform to idiomatic English. This detailed description should be read to include one or at least one, and the singular also includes the plural unless it is clearly indicated otherwise.

A subsea connector apparatus and system having a reconfigurable cartridge may comprise, consist of, or consist essentially of at least one cables 100, at least two connectors 200, and a reconfigurable cartridge 300. Each of the connectors 200 may be electrically connected to a cable 100 and, additionally, may selectively be coupled to another connector 200. This includes a symmetrical or asymmetrical counterpart connector 200. This selective coupling means that the connectors may either be in a connected or disconnected configuration, the connected position enabling a proper “connection”. Furthermore, the cartridge 300 may be configured to be compressed between two connected connectors 200 and facilitate their electrical connection. The cartridge 300 is readily removable and replaceable with another cartridge 300 that may facilitate alternative connections, in some embodiments. An electrical connection is created through female sockets in the connectors 200 and male pins on each side of the cartridge 300, which is dual-sided. In some embodiments, the reconfigurable cartridge 300 may further comprise symmetrical, or asymmetrical pin arrangements.

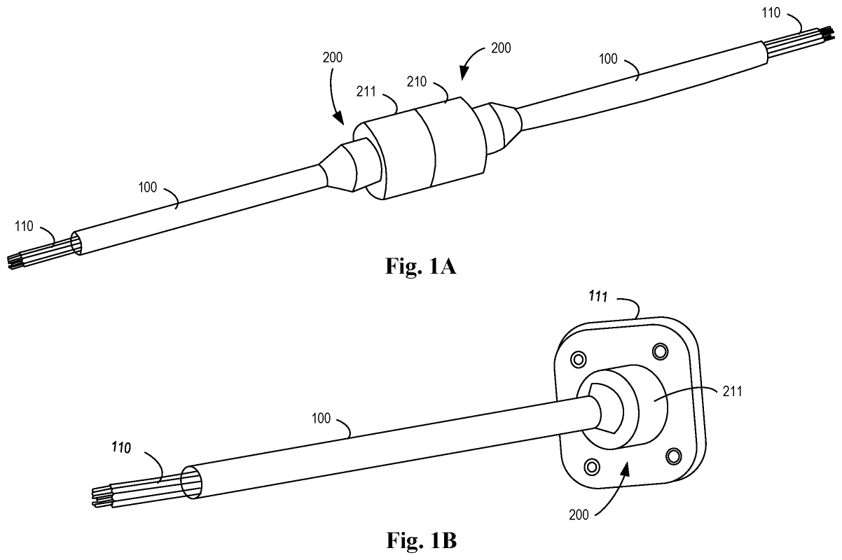

Additionally, each of the connectors 200 may be coupled to a bulkhead connector 111, which may be located on an aquatic or sub aquatic vessel and facilitate an electrical connection to the vessel, as shown in FIG. 1B. The bulkhead connect 111 may, in one embodiment, thread into the pressure housing. This may reduce the need for cable connections downstream in some design application and would provide various benefits such as requiring less space.

The subsea connector apparatus and system may be used in aquatic environments or any environment where an isolated electrical connection is advantageous. As described herein, the subsea connector apparatus and system facilitate the electrical connection of at least two systems, where the electrical connection may carry power or data. Examples of systems may include, but are not limited to, submersible underwater vehicles, moored buoys, and sensor-based systems that collect data underwater. In one embodiment, the cable 100, connectors 200, and cartridge 300 may further comprises metal shells for applications that require shielding from electromagnetic interference.

FIG. 1 shows an exemplary isometric illustration of a subsea connector apparatus and system in a connected position comprising at least two cables 100 having a plurality of individual conductors 110, at least two connectors 200, a male locking sleeve 210, and a female locking sleeve 211. The cables 100 may be electrically connected to at least two external systems. The conductors 110 are carried by the cable, typically surrounded by an electrically insulating material, and may facilitate power and data transmission of data between the at least two systems. In one embodiment, these cables are identical, meaning they may facilitate symmetrical transmission of power and/or data. The universality of symmetrical cable design provides for simplified manufacturing and design.

Furthermore, FIG. 1 shows two connectors, with one having a male locking sleeve 210 and the other having a female locking sleeve 211. These connectors are in a closed position so that the internal electrical connections are isolated from the surrounding environment. The locking sleeves compress the cable assemblies onto the cartridge and form a seal. Furthermore, the male locking sleeve 210 and female locking sleeve 211 encapsulate the connectors 200 and seal the connections via the male locking sleeve 210 sliding snuggly inside of the female locking sleeve 211. A tight fit of the locking sleeve seals the internal connections from the environment through tight tolerances and/or a compressive force. In some embodiments, the male locking sleeve 210 further comprises external threads that interlock with a female locking sleeve 211 further comprising internal threads configured to provide additional compressive force and sealing effects. The tightening of the threads creates the compression for sealing.

Finally, FIG. 1 shows the overall assembly of a subsea cable and connector apparatus and system with locking sleeves installed and the ends of the cable bare showing the conductors for illustration purposes. In practice, the cable 100 and conductors 200 may go to another connector 200, or to a bulkhead connector 200 or potted to a completely different cable depending on user requirements.

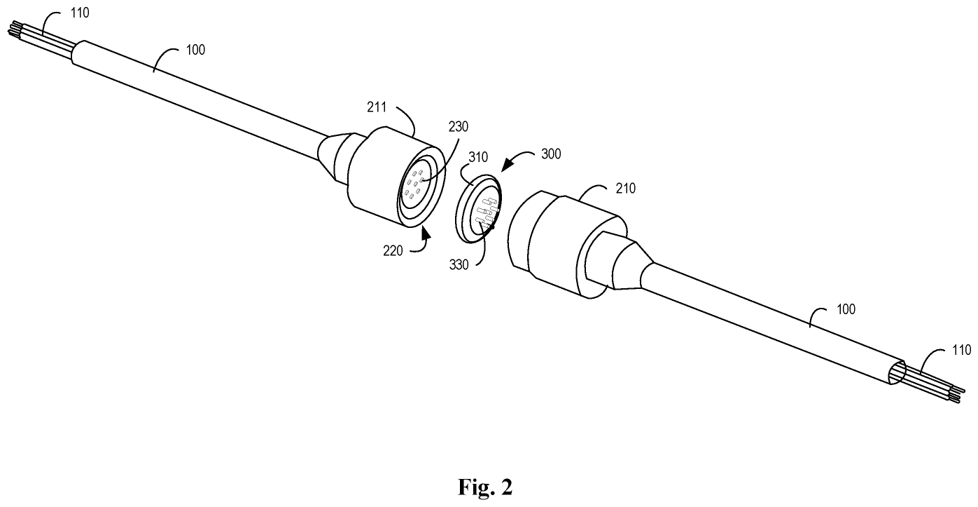

FIG. 2 shows an exemplary isometric illustration of the subsea connector in an open (i.e. disconnected) position comprising at least two cables 100 having a plurality of individual conductors 110, at least two connectors 200, a male locking sleeve 210, a connector face 220, a female locking sleeve 211, a plurality of female socket contacts 230, a cartridge 300, metal ring 310, and a plurality of male pins 330. The exemplary cable assembly is shown in FIG. 2 comprises two identical connectors 200 (i.e. symmetrical connectors) containing female sockets 230 which mate to a cartridge 300 with a plurality of male pin contacts 330. However, the connectors must not necessarily be symmetrical or identical. The connector face 220 or the configuration of the female sockets 230 may be asymmetric. Again, the FIG. 2 illustration shows the conductor wires as exposed, for illustrative purposes.

The cartridge 300 is dual-sided and responsible for forming a connection between at least two cables 100 and this can be a pass-through 323 connection in the cartridge 300 via the male pin contacts 330. For example, the connection may pass through from one pin on a first side to a second pin one pin on a second side, or pass through from a first pin to pin a different pin on the second side. The configurations of pins and electrical connections may be configured by an internal printed circuit board (PCB) 320 or connections potted inside the cartridge 300 assembly. The cartridge 300 may be readily interchangeable and reconfigurable to be replaced easily and adapt to new operation requirements. In an additional embodiment, the PCB 320 may be produced without existing connections, but provide space for a user or operator to add connections directly to the PCB 320 (e.g. by soldering) so that the cartridge is readily customizable for an application.

In some embodiments, the cartridge 300 has a diameter less than or approximately equal to the male locking sleeve, so that the locking sleeve can fully encapsulate the cartridge 300 and at least two sockets. Furthermore, FIG. 2 shows the connectors 200 and cartridge 300 as having a cylindrical shape wherein the electrical current flows through its longitudinal axis. However, the shape is not limited to a cylinder, and the shape may vary while still permitting electrical isolation from the environment, current flow, and reconfigurability. In the cylindrical embodiment, a metal ring 310 may surround the cylindrical surface of the cartridge 300. The seal is formed by particular geometry including the metal ring 310 of the cartridge 300.

The face 220 comprises, consists of, or consists essentially of a plurality of female sockets 230 embedded in the face 220, at least two connector sealing surfaces surrounding the plurality of female sockets, and at least one alignment hole 240. The connector sealing surfaces surround and isolate the plurality of female sockets to provide sealing against environmental conditions such as water. Furthermore, connector sealing surfaces have counterparts on the cartridge 300 and provide isolation from the environment which in some embodiments, includes water. These counterparts mate together to form a seal, and are described below as sealing surfaces” and, in some embodiments, a primary sealing surface, secondary sealing surface, and tertiary sealing surface. In FIG. 2, three sealing surfaces are shown on the connector face 220. Regarding the alignment hole 240, at least one hole 240 allows and an alignment pin 340 to mate with the hole and align the connector 200 with the cartridge 300. These components of the face 220 may directly interface with the cartridge to provide sealing or electrical connection.

The plurality of female contact sockets 220 are embedded in each connector face 220 within the compressive seal of the locking sleeve and are configured to mate with the male contact pins 330. In some embodiments, the female contact sockets 220 may be potted in urethane. Furthermore, the plurality female contact sockets 220 may comprise a variety of configurations, comprising different numbers of sockets 220 and different socket arrangements. For example, the number of contacts may range from two to sixteen. In this disclosure, uniquely, the configuration and presence of female contacts 220 may be symmetrical to those of an opposite connector 200.

As discussed previously, a plurality of male pin contacts 330 are embedded in the cartridge 300 and are configured to mate with the female contact sockets 220. The cartridge 300 is dual sided so that pins 320 on the first side are each electrically connected to at least one pin on the second side. The electrical connections may be traces or soldered, in some exemplary embodiments, via a PCB.

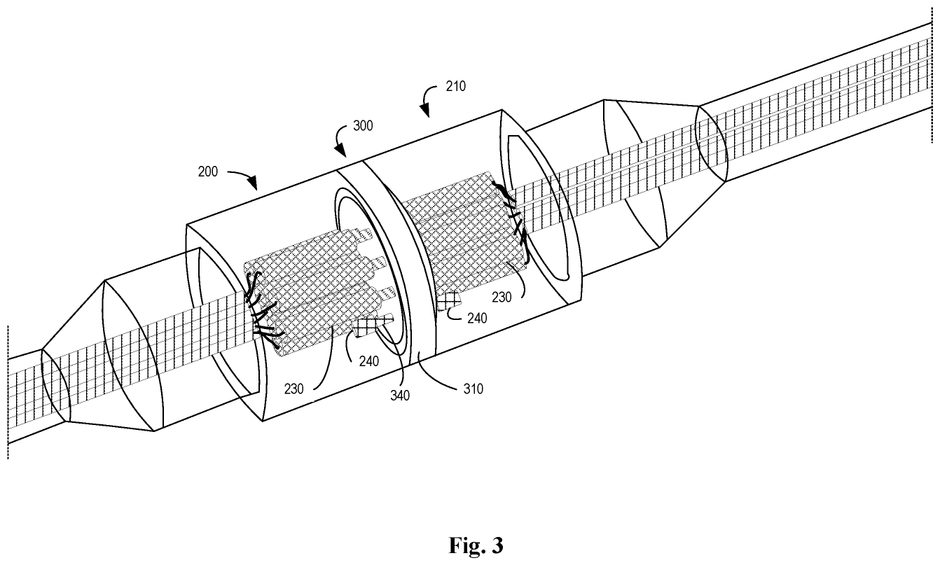

FIG. 3 shows an exemplary wireframe illustration of a subsea connector apparatus and system in a connected position comprising at least two connectors 200, a male locking sleeve 210, a female locking sleeve 211, a plurality of female socket contacts 230, a cartridge 300, metal ring 310, and a plurality of male pins 330. Moreover, this zoomed-in and transparent view comprises the cartridge 300, further comprising a PCB that forms the connection internally between the male pins 330 on both sides of the cartridge 300 and ultimately to each cable 100 on both sides. The male pins 330 are mated (i.e. in the closed configuration) with the female socket contacts 230. Additionally, FIG. 3 illustrates the female alignment hole 240 and male alignment pin 340 that may exist in each cable assembly so it docks properly when mated to the cartridge. The alignment hole 230 is a feature that allows the alignment pin 340 to dock and not make electrical contact with the conductors, traces, or lines of soldering. In some embodiments, at least one alignment pin exists on each side of a dual-sided cartridge 300. Additionally, each connector 200 has an alignment hold optimally positioned to align with at an alignment pin 330.

In the exemplary illustration of FIG. 3, the conductor wires 110 are soldered to the female socket contacts 230 as shown by the bolded lines from the wires 110 to the sockets 230. As a note, the female sockets 230 may be held in place with some type of tooling/mold assembly during the potting process after the wires are soldered to them. This embodiment (FIG. 3) shows the subsea connector apparatus and system are potted in urethane for sealing and readiness for underwater applications.

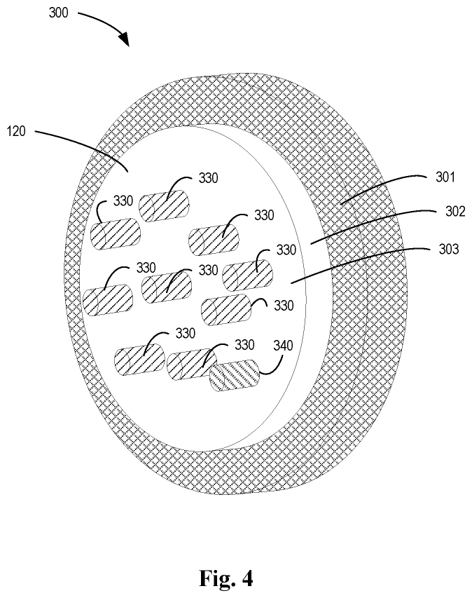

FIG. 4 shows an exemplary illustration in an isometric view of a cartridge 300 having a PCB assembly and comprising a plurality of male contact pins 330, an alignment pin 340, a primary sealing surface 301, a secondary sealing surface 302, a tertiary sealing surface 303, and a rubber potting cover 120. As described previously, the cartridge 300 is dual-sided and responsible for forming a connection between at least two cables 100 and this can be a pass through a connection in the cartridge 300 via the male pin contacts 330 on the PCB 320. The connection passed through via electrical connections between the pins 330 on each side of the PCB 320. Because the PCB can be quickly and easily manufactured, an opportunity exists to adapt electrical connectors to specific needs without redesigning the external systems.

Configurability, reuse, and adaptation of this disclosure may involve changing the pattern of pins 330 on each side of the cartridge 300 and/or changing how the pins on each side of cartridge 300 are interconnected. In some embodiments, the male pin 330 configurations are symmetrical. For example, the connection may pass through from one pin on a first side to one pin on a second side. However, in another embodiment, the connection may pass through from one pin on a first side to a different pin on the second side. The configurations of pins and electrical connect may be configured by a printed circuit board (PCB) or connections potted inside the cartridge assembly. The cartridge 300 may be readily interchangeable and reconfigurable to be replaced easily and adapt to new operation requirements.

Additionally, the PCB 320 may further comprise a splitter, wherein asymmetrical pin configurations facilitate a first cable 100 on one of the dual-sided PCB 320 to be electrically connected to a different pin configuration on another side facilitating at least two cables 100. A splitter may enable a connection from one cable 100 to two cables 100 or, in other words, the splitter may have having an additional male pin arrangement operable to connect a third cable. For example, the PCB may have a rectangular shape with one arrangement of male pins 330 on one side and two adjacent arrangements of male pin 330 configurations on the opposite side (for two cables). However the splitter may be enabled by other shapes of the PCB as well, including arrangements on multiple, non-parallel plains such as utilizing multiple sides of a cube. This embodiment may be beneficial in situations where the cables 100 have extra conductors so as to incorporate them into future use cases. The splitter utilizes either a sealing configuration identical to those previously described, simply as an additional sealed connection, or may be completely encompassed by the sealing surfaces of an adjacent connection, effectively sharing sealing surfaces.

The cartridge 300 may also have asymmetrical pin configurations in some embodiments. As an exemplary asymmetrical configuration, one side of the cable 100 and connector 200 may distribute power to multiple devices (via pins) and the other side of the cable 100 and connector 200 may be connected to a larger power source requiring a single larger conductor. Therefore, one side may have 6 pins, for example, while the other side has 4 or 5 pins. In another embodiment, various configurations could involve electrical grounding.

As another example, one single source may distribute to a multi-talker communications bus such as single pair Ethernet, or serial RS485 or 422, and/or a power to multiple loads this could be facilitated by using an asymmetrical arrangement. Moreover, an example would be using an 8-pin connector on the source side which included 3 pins for RS485, 4 pins for power (optionally at 2 different voltages) and a single shield pin connecting to a 16-pin connector on the other side where parallelization of the signals is completed in the PCB cartridge. The mating connector may be molded onto a pair of cable assemblies. This may offer benefits over a typical Y connector in terms of a more compact connection.

In one embodiment, the number of sealing surfaces on each side is three: a primary sealing surface 303, secondary sealing surface 302, and a tertiary sealing surface 303. The primary 301, secondary 302, and tertiary sealing surfaces 303 isolate the electrical connections between the connectors 200 and the cartridge. For example, the sealing surfaces enable the isolation of electrons in aquatic embodiments subject to high hydrostatic pressures. All sealing surfaces may be formed by proper tolerance manufacturing and slight oversizing of geometrical features of the cartridge assembly so mating is done with slight interference. Each sealing surface on the cartridge 300 has a counterpart sealing surface on each of the connector face 220, described previously as the connector sealing surface. Moreover, the sealing surfaces may be symmetrical on each side of the cartridge, in some embodiments.

The primary sealing surface 301 is directly adjacent to and internal to the locking sleeve, surrounding the plurality of male pins 330 on each side of the dual-sided cartridge. Multiple forces are utilized for sealing the primary sealing surface 301, including compression from the locking sleeves being all the way tight and also some help from hydrostatic pressure when the assembly goes beneath the surface of the water.

The secondary sealing surface 302 is orthogonal to the primary sealing surface 301, extending outward from each side of the dual-sided cartridge, terminating at an orthogonal tertiary sealing surface 303. As illustrated in FIG. 4, the primary sealing surface 301 is the flat (i.e. opposed to the cylindrical face), outward-facing side of the cartridge surrounding the pins 320 and potting material 120. The tertiary sealing surface 303 is parallel to the primary surface 301 on a potted 120 surface extending further from the primary sealing surface 301. The secondary sealing surface 302 is found orthogonal to each of these planes surrounding the protruded tertiary sealing surface 303 and has a similar shape to that of the cartridge 300 (e.g. a cylinder). The secondary sealing surface 302 is operable by careful dimension and tolerance manufacturing. For instance, the diameter of the secondary sealing surface 302 for the connector 200 can be undersized say 0.750 inches with a tolerance of −0.010 and the diameter of the secondary sealing surface 302 for the cartridge 300 could be larger say 0.760 inches with a tolerance of +0.010 so there may be a slight forced fit.

The tertiary sealing surface 303 is an outward face of the cartridge 300 adjacent to the base of the plurality of male pins 330 interface, comprising potting material. The tertiary sealing surface directly interfaces with the connector's 200 surface to seal the connection when tightly pressed together. The connector 200 has a potted surface with a mirrored geometry to seal against. In one embodiment, the locking sleeves may contribute to compressing the tertiary sealing surface.

In another embodiment, the male pins 330 may be partially encapsulated by rubber or urethane around the pin, and the female contact sockets 230 may have a recess for the contact pins in the cable so there is more rubber contact. Partial encapsulation of male pins is commonly utilized in subsea connectors and may be utilized however this may require more sophistication in the molding process of the cartridge.

Regarding the connections, comprising the wires 110, female socket contacts 230, and male contact pin 330, the connections may facilitate both power and communications. The pin size (i.e. diameter) is determined according to how much current is flowing through it to facilitating power. Generally the pin diameter will be at least the diameter of the gauge wiring required. However, there may be some embodiments where twisted wire pairs feeding to the pins may be desirable and/or possibly some shielding which may require more thought on how to preserve the shielding if a cartridge is utilized.

Limitations on power connections may be determined by connector voltage which is determined primarily by the insulation resistance which depends upon the specific material properties of insulators as well as the geometric density of the pins (the proximity of individual pins to each other). Current through an individual pin would be limited primarily by the heat tolerance of the materials in question as well as the availability of external cooling (i.e. seawater). Undersea connectors typically have a different current rating wet vs dry, which may be implemented herein.

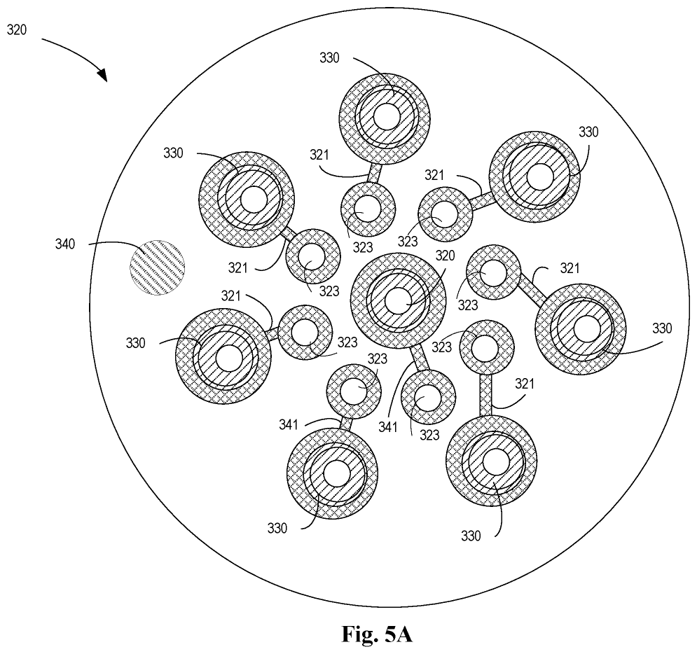

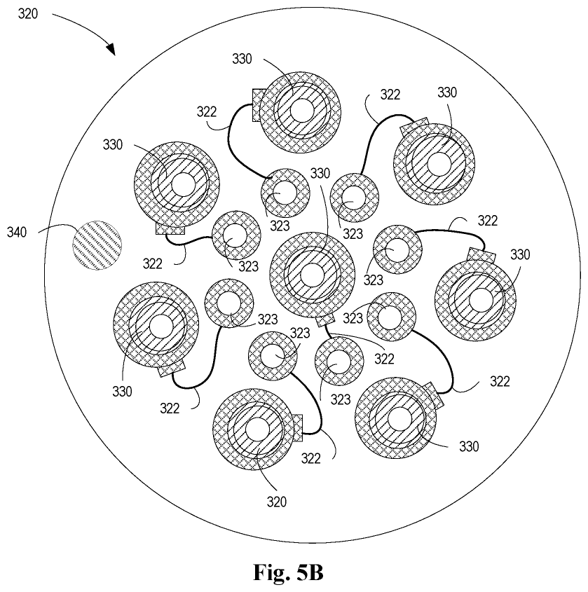

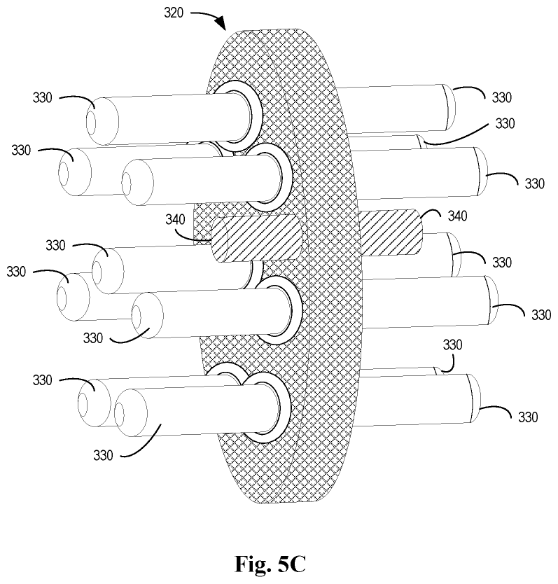

FIG. 5A shows an exemplary front-view illustration of a PCB assembly 320 comprising PCB traces 321, a plurality of male contact pins 330, a plurality of pass-through holes 323, and an alignment pin 340. The PCB assembly 320, in FIGS. 5A and 5B, is shown as part of the cartridge 300 without potting 120 with eight male contact pins 330 soldered to the surface pad of the PCB on both sides. As previously discussed, this pin configuration is an example and could number two to sixteen, or more. A connection between pins on both sides of the circuit board is made by a plurality of pass-through holes 323, which is conductive. In FIG. 5A the connection from the male pins on one side to the other is made by traces 321. In FIG. 5B the connection between sides is made by soldering. The PCB assemblies 320 may be preconfigured and an operator may have a variety of configurations at hand to utilize the ones needed for the particular application. Finally, the last described component, the alignment pin 330, is a hole that allows the alignment pin to slide through and not make any electrical contact with the conductors or traces of the PCB. In some embodiments, the PCB assembly 320 may be potted in urethane along and/or encapsulated around the rim with a metal ring.

FIG. 5B, in an alternative embodiment, shows an exemplary front-view illustration of a PCB assembly comprising soldered connections 322, a plurality of male contact pins 330, a plurality of pass-through holes 323, and an alignment pin 340. In the embodiment shown in FIG. 5B, an operator may utilize the soldering wire tabs to make a manual wire connection by soldering to the tab and to the via of choice using standard jacketed wire conductors. This allows a user to make on the fly change the configuration manually. For example, the assembly may be potted in urethane using, for instance, a manufacturer-supplied tooling kit consisting of a mold, urethane, and other special hardware. In this example, pin #1 on a left side may connect to pin #1 on a right side and the same could apply to additional pins. However, a user may reconfigure these connections to any desired configuration. For instance, if a new sensor requires a different wiring configuration but the operator wishes to leave the pressure housing and internal electronics intact, a new cartridge can be made if a stock combination isn't able to achieve the desired connection.

FIG. 5C shows an exemplary side-view illustration of a PCB assembly 320 comprising a plurality of male contact pins 330 and an alignment pin 340. This figure well-illustrates a PCB assembly 340 and how each of the male pins extends outward from the flat faces of the PCB 340.

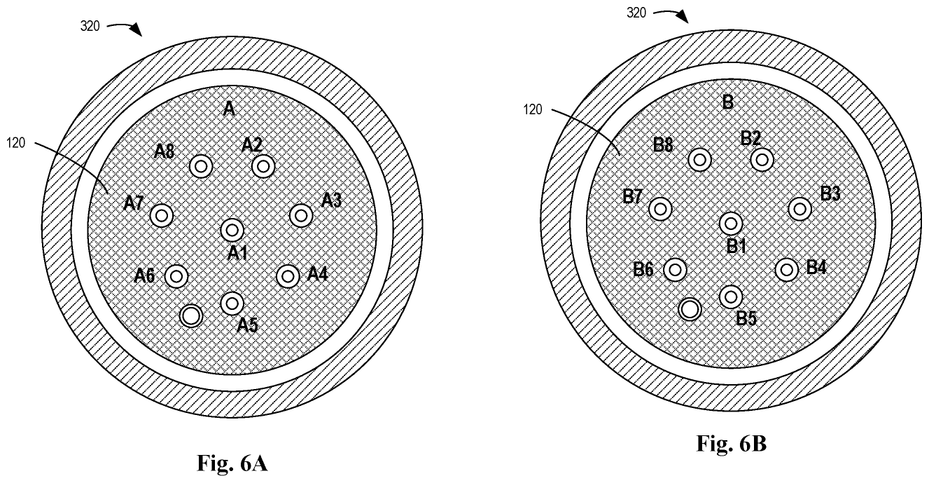

FIGS. 6A and 6B show exemplary pinout configurations comprising pin labels A1-A8 on Side “A” or B1-B8 on Side “B”. These labels may serve multiple purposes. In one embodiment, pin labels may be included in a user guide or printed onto the surface of the potting material of the cartridge 300. This may be accomplished with the lettering and numbering embossed or indented in the urethane, for example, the molds may have the inherent features such that when the urethane is poured the lettering/numbering would automatically show up once the urethane is cured and mold parts released. In another embodiment, pin layouts may be used as an illustration for a user to identify how a connection is made. In these figures Side “A” comprises male pins 330 numbers A1-A8 and Side “B” comprising male pins 330 numbered B1-B8. A1 could map to B1, or A2 to B3, or such configuration. The internal traces/wiring in the PCB 320 is what allows a change from what the Side “A” of the cartridge connects to on Side “B”. Therefore, pin labels may be helpful in multiple instances either printed on the cartridge 300 or described in a pin layout guide.

From the above description of Reconfigurable Cartridge Based Subsea Connector Apparatus and System, it is manifest that various techniques may be used for implementing the concepts of symmetrical subsea connector apparatus, asymmetrical subsea connector apparatus, and symmetrical subsea connector system without departing from the scope of the claims. The described embodiments are to be considered in all respects as illustrative and not restrictive. The method/apparatus disclosed herein may be practiced in the absence of any element that is not specifically claimed and/or disclosed herein. It should also be understood that symmetrical subsea connector apparatus, asymmetrical subsea connector apparatus, and symmetrical subsea connector system are not limited to the particular embodiments described herein, but is capable of many embodiments without departing from the scope of the claims.

What is claimed:

1. A symmetrical subsea connector apparatus, comprising:
a connector further comprising:
a face comprising a plurality of female sockets embedded in the face, at least three connector sealing surfaces surrounding the plurality of female sockets, and at least one alignment hole, and
a female locking sleeve surrounding the outer edge of the face and operable to provide a compressive seal when mated with a male locking sleeve;
a symmetrical connector configured to selectively couple with the connector, further comprising:
a symmetrical face comprising a plurality of symmetrical female sockets embedded in the symmetrical face, at least three sealing surfaces surrounding the plurality of symmetrical female sockets, and a plurality of symmetrical alignment holes, and
the male locking sleeve surrounding the outer edge of the symmetrical face operable to provide a compressive seal when mated with the female locking sleeve; and
an interchangeable dual-sided cartridge configured to selectively intermediate a connection between the connector and symmetrical connector, further comprising:
a printed circuit board (PCB), having a first side, a second side, and a plurality of pass through holes further comprising a plurality of interconnections,
a plurality of male contact pins coupled to each of the first side and the second side of the PCB, wherein the configuration of the plurality of male contact pins is aligned to selectively mate with the plurality of female sockets on the first side and the plurality of symmetrical female sockets on the second side, and wherein each male contact pin is interconnected is a pin on the other side,
a first potted face having aligned pass through openings for the plurality of male pins on the first side, and a second potted face having aligned pass through opening for the plurality of male pins on the second side,
at least three sealing surfaces on each side surrounding the plurality of male contact pins,
at least two alignment pins protruding from each of the first side and the second side of the PCB, wherein the configuration of the alignment pins aligned to selectively mate with the alignment holes of each of the face and symmetrical face.

2. The symmetrical subsea connector apparatus of claim 1, wherein the plurality of interconnections on the PCB comprise traces.

3. The symmetrical subsea connector apparatus of claim 1, wherein the plurality of interconnections on the PCB comprise soldering connections.

4. The symmetrical subsea connector apparatus of claim 1, further comprising:
a cable electrically connected to the connector; and
a symmetrical cable electrically connected to the symmetrical connector.

5. The symmetrical subsea connector apparatus of claim 1, further comprising:
a cable electrically connected to the connector; and
a bulkhead housing coupled to the symmetrical connector.

6. The symmetrical subsea connector apparatus of claim 1, wherein each of the plurality of male contact pins are partially encapsulated by rubber, and the plurality of female sockets and plurality of symmetrical female sockets are recessed.

7. The symmetrical subsea connector apparatus of claim 1, wherein the number of sealing surface on each side is three, each side further comprising:
a primary sealing surface adjacent to the locking sleeve;
a secondary sealing surface orthogonal to the primary sealing surface, extending outward from each side of the dual-sided cartridge; and
a tertiary sealing surface adjacent the base of the plurality of male contact pins.

8. A asymmetrical subsea connector apparatus, comprising:
a connector, electrically connected to a cable, further comprising:
a face comprising a plurality of female sockets embedded in the face, at least three connector sealing surfaces surrounding the plurality of female sockets, and at least one alignment hole, and
a female locking sleeve surrounding the outer edge of the face and operable to provide a compressive seal when mated with a male locking sleeve;
a asymmetrical connector, electrically connected to a second cable, configured to selectively couple with the connector, further comprising:
a asymmetrical face comprising a plurality of asymmetrical female sockets embedded in the asymmetrical face, at least two asymmetrical connector sealing surfaces surrounding the plurality of asymmetrical female sockets, and a plurality of alignment holes, and
the male locking sleeve surrounding the outer edge of the asymmetrical face operable to provide a compressive seal when mated with the female locking sleeve; and
an interchangeable dual-sided cartridge configured to selectively intermediate a connection between the connector and asymmetrical connector, further comprising:
a printed circuit board (PCB), having a first side, a second side, and a plurality of pass through holes further comprising a plurality of interconnections,
a plurality of male contact pins coupled to the first side and the second side of the PCB, wherein the configuration of the plurality of male contact pins is aligned to selectively mate with the plurality of female sockets on the first side and the plurality of female sockets on the second side,
a first potted face having aligned pass through openings for the plurality of male pins on the first side, and a second potted face having aligned pass through opening for the plurality of male pins on the second side,
at least three sealing surfaces on each side surrounding the plurality of male contact pins,
at least two alignment pins protruding from each of the first side and the second side of the PCH, wherein the configuration of the alignment pins aligned to selectively mate with the alignment holes of each of the face and asymmetrical face.

9. The asymmetrical subsea connector apparatus of claim 8, wherein the plurality of interconnections on the PCB comprise traces.

10. The asymmetrical subsea connector apparatus of claim 8, wherein the plurality of interconnections on the PCB comprises soldered connections.

11. The asymmetrical subsea connector apparatus of claim 8, further comprising:
a cable electrically connected to the connector; and
a symmetrical cable electrically connected to the symmetrical connector.

12. The asymmetrical subsea connector apparatus of claim 8, further comprising:
a cable electrically connected to the connector; and
a bulkhead housing coupled to the asymmetrical connector.

13. The asymmetrical subsea connector apparatus of claim 8, the dual-sided cartridge further comprising:
a splitter having an additional male pin arrangement operable to connect a third cable.

14. The asymmetrical subsea connector apparatus of claim 8, wherein each of the plurality of male contact pins are partially encapsulated by rubber, and the plurality of female sockets and plurality of asymmetrical female sockets are recessed.

15. The symmetrical subsea connector apparatus of claim 8, wherein the number of sealing surface on each side is three, each side further comprising:
a primary sealing surface adjacent to the locking sleeve;
a secondary sealing surface orthogonal to the primary sealing surface, extending outward from each side of the dual-sided cartridge; and
a tertiary sealing surface adjacent the base of the plurality of male contact pins.

16. A subsea connector system, comprising:
a first connector, electrically connected to a cable, further comprising:
a face comprising a plurality of female sockets embedded in the face, at least three connector sealing surfaces surrounding the plurality of female sockets, and at least one alignment hole, and
a female locking sleeve surrounding the outer edge of the face and operable to provide a compressive seal when mated with a male locking sleeve;
a second connector, electrically connected to a second cable, configured to selectively couple with the connector, further comprising:
a second face comprising a plurality of second female sockets embedded in the second face, at least three connector second sealing surfaces surrounding the plurality of second female sockets, and a plurality of alignment holes, and
the male locking sleeve surrounding the outer edge of the second face operable to provide a compressive seal when mated with the female locking sleeve; and
a plurality of interchangeable cartridges, each configured to selectively intermediate a connection between the connector and second connector, and wherein each of the plurality of interchangeable cartridges provides a unique connection configuration, further comprising:
a printed circuit board (PCB) having a first side and a second side,
a plurality of male contact pins coupled to the first side and the second side of the PCB, wherein the configuration of the plurality of male contact pins is aligned to selectively mate with the plurality of female sockets on the first side and the plurality of female sockets on the second side,
a first potted face having aligned pass through openings for the plurality of male pins on the first side, and a second potted face having aligned pass through opening for the plurality of male pins on the second side,
at least three sealing surfaces on each side surrounding the plurality of male contact pins,
at least two alignment pins protruding from each of the first side and the second side of the PCB, wherein the configuration of the alignment pins aligned to selectively mate with the alignment holes of each of the face and second face.

17. The subsea connector system of claim 15, wherein the plurality of interconnections on the PCB comprise traces.

18. The subsea connector system of claim 15, wherein the plurality of interconnections on the PCB comprises soldered connections.

19. The asymmetrical subsea connector apparatus of claim 8, further comprising:
a cable electrically connected to the connector; and
a symmetrical cable electrically connected to the symmetrical connector.

20. The asymmetrical subsea connector apparatus of claim 8, further comprising:
a cable electrically connected to the connector; and
a bulkhead housing coupled to the asymmetrical connector.
